(19) United States
(12) Patent Application Publication
(10) Pub. No.: US 2006/0272940 A1
(43) Pub. Date: Dec. 7, 2006

(54) System and a method using RFID tags for tracing a production process of discs

(76) Inventor: Liang Su, Miaoli Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/143,470

(22) Filed: Jun. 3, 2005

(51) Int. Cl. C23C 14/00

(52) U.S. Cl. 204/298.01

(57) ABSTRACT

A system and a method using RFID tags for tracing a production process of discs, wherein the system comprises a disc spindle, which has an RFID tag, and a plurality of readers. The disc spindle cooperates with the readers to control the production process of discs that pass through a dye-coating station, a metal-sputtering station, a gluing station and a checking station. The method provides a disc spindle having an RFID tag and a plurality of readers. The RFID tag contains related production information about the discs. The disc spindle cooperates with the readers, during the dye-coating, metal-sputtering, gluing, checking, printing, and packing steps, and transmits processing data to each station respectively concerning the substrates as they are proceeding through each step for tracing the production process of the discs.

### BACKGROUND OF THE INVENTION

1. Field of the Invention

The present invention relates to a system and a method for tracing a production process of discs, and more particularly, to a system and a method for tracing a production process of discs, which uses RFID tags to control the production process of discs.

2. Description of the Related Art

At present, in the production process of discs, an operator on a production line utilizes a method using either work orders or bar codes to record the production data of each batch of discs on a spindle. That is for controlling the production of discs. This method suffers in that a wrong data will be recorded or data will be missed due if a work order or bar code is missed or is faulty.

Therefore, in order to control the quality and the quantity of discs, the disc producer hopes to track the production condition of each batch of discs via RFID technology throughout the process, recording each item's processing data from the injection forming stage to the final packing stage. The RFID method solves the problem of the conventional method for controlling the production condition of discs and achieves accuracy and fluency in the production process.

### SUMMARY OF THE INVENTION

It is therefore a principal objective of the present invention to provide a system and a method for tracing a production process of discs, which use RFID tags to control the production process of discs.

To achieve the above objective, one feature of the present invention is provided by a system using RFID tags for tracing a production process of discs, comprising:

At least one disc spindle bearing a plurality of substrates; at least one RFID tag attached to the disc spindle, and containing production information for each batch of discs;

A dye-coating station used for coating dye to the substrates; a metal-sputtering station used for sputtering metal targets to the dyed substrates, and being downstream of the dye-coating station;

A gluing station used for gluing each of the metal-sputtered substrates with a dummy to form a disc, and being downstream of the metal-sputtering station;

A checking station used for checking the glued metal-sputtered substrates to determine the quality of each batch of discs, and being downstream of the gluing station; and

A plurality of readers disposed at each of the stations respectively, and cooperating with the RFID tag to transmit the production information of each batch of discs to be contrasted with production data from each station and for controlling the production process of the discs.

To achieve the above objective, another feature of the present invention is a method using RFID tags for tracing the production process of discs, comprising:
(a) providing at least one disc spindle having an RFID tag and a plurality of readers receiving processing data from the RFID tag or transmitting processing data to the RFID tag;
(b) placing a plurality of substrates on the disc spindle having the RFID tag;
(c) transmitting processing data to a first reader informing the information system that the substrates are proceeding to the dye-coating station;
(d) coating the substrates with a dye;
(e) transmitting processing data to a second reader informing the information system that the substrates are proceeding to the metal-sputtering station;
(f) sputtering the substrate with metal targets;
(g) transmitting processing data to a third reader informing the information system that the substrates are proceeding to the gluing station;
(h) gluing each of the metal-sputtered and dyed substrates with a dummy;
(i) transmitting processing data to a fourth reader informing the information system that the substrates are proceeding to the checking station;
(j) checking the substrates;
(k) transmitting processing data to a fifth reader informing the information system that the substrates are proceeding to the printing station;
(l) printing the substrates;
(m) transmitting processing data to a sixth reader informing the information system that the substrates are proceeding to the packaging station; and
(n) packing the substrates.

To provide a further understanding of the invention, the following detail description illustrates embodiments and examples of the invention, this detailed description being provided only for illustration of the invention.

### BRIEF DESCRIPTION OF THE DRAWINGS

The drawings included herein provide a further understanding of the invention. A brief introduction of the drawings is as follows:

FIG. 1 is a sketch view of the system using an RFID tag for tracking a production process of discs of the present invention.

FIG. 2 is a flowchart of the method using an RFID tag for tracking a production process of discs of the present invention.

### DETAILED DESCRIPTION OF PREFERRED EMBODIMENTS

Referring now to the drawings wherein the showings are for purposes of illustrating preferred embodiments of the present invention only, and not for purposes of limiting the same.

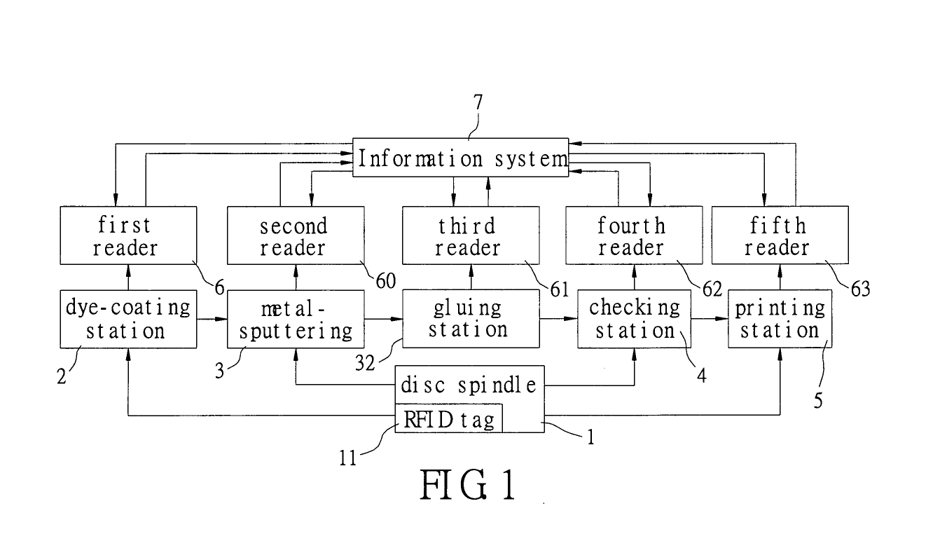

Referring to FIG. 1, which is a sketch view of the system using an RFID tag for tracking a production process of discs of the present invention. The present invention provides a system using an RFID tag for tracking a production process of discs, comprising a disc spindle 1, an RFID tag 11, a dye-coating station 2, a metal-sputtering station 3, a gluing station 32, a checking station 4, a printing station 5, a first reader 6, a second reader 60, a third reader 61, a fourth reader 62, a fifth reader 63, and an information system 7.

The information system 7 is used for receiving transmitted processing data from each of the readers 6, 60, 61, 62, and 63 through a network or a computer. The readers 6, 60, 61, 62, and 63 were disposed respectively to each of stations. The readers 6, 60, 61, 62, and 63 cooperate with the RFID tag 11 attached to the disc spindle 1 to transmit production information of each batch of discs, including the quality and the quantity of the discs and the production condition of each of the stations for contrasting with production data for each station and for controlling the production process of the discs.

The disc spindle 1 bears a plurality of substrates. The RFID tag 11 is attached to the disc spindle 1, and contains the product information for each batch of discs. The disc spindle 1 with the RFID tag 11 is used for controlling the production process of the discs. Therefore, when the disc spindle 1 has finished bearing the substrates and it moves forward to the dye-coating station 2 to be coated with dye. The first reader 6 disposed at the dye-coating station 2 transmits a signal periodically to the RFID tag 11 disposed on the disc spindle 1. Next the circuitry of the RFID tag 11 that received the signal from the first reader 6 makes sure that the substrates proceed to the dye-coating station 2 to be coated with dye. Next, the signal that was transmitted between the first reader 6 and the RFID tag 11 is transmitted to the information system 7 through a network or a computer. The information system 7 reads the signal through a different program to provide a message for the operator on the production line to check and control the discs in the production process.

The dye-coating station 2 is used for coating dye on the substrates placed on the disc spindle 1 having the RFID tag 11. The substrates pass through six coating tanks respectively to finish the dye-coating process. They are then sprayed with an IJP code. Then passed through an oven for baking, or air-drying. They then proceed to the metal-sputtering station 3 to be sputtered with metal (Ag, or Au) target. The second reader 60 disposed at the metal-sputtering station 3 then transmits a signal periodically to the RFID tag 11 disposed on the disc spindle 1. Then the circuitry of the RFID tag 11 that received the signal from the second reader 60 make sure that the dyed substrates go forward to the metal-sputtering station 3 to be sputtered with metal targets. Next, the signal that was transmitted between the second reader 60 and the RFID tag 11 is transmitted to the information system 7 through a network or a computer. The information system 7 reads the signal through a different program to provide a message for the operator on the production line to check and control the discs in the production process.

The metal-sputtering station 3 is used for sputtering metal targets to the dyed substrates, and is downstream from the dye-coating station 2. The dyed substrates are sputtered with metal targets using the principle of vacuum absorption. Then the bead on the edge of the metal-sputtered dyed substrates is removed with edge bead removers, and LQ glue is coated onto the surface of the metal-sputtered dyed substrates. Next, a UV lamp is used to dry the metal-sputtered dyed substrates for solidification, and each of the metal-sputtered dyed substrates will proceed to the gluing station 32 to be glued with a dummy (this is the same process as for a DVD, but different from the process for a CD. The metal-sputtered dyed substrates that have been coated with the LQ glue at this stage proceed directly to the checking station 4 to be checked). The third reader 61 disposed at the gluing station 32 transmits a signal periodically to the RFID tag 11 disposed on the disc spindle 1. Then the circuitry of the RFID tag 11 that received the signal from the third reader 61 makes sure that each of the metal-sputtered and dyed substrates proceeds to the gluing station 32 to be glued with a dummy. The signal that was transmitted between the third reader 61 and the RFID tag 11 is transmitted to the information system 7 through a network or a computer. The information system 7 reads the signal through a different program to provide a message for the operator on the production line to check and control the discs in the production process.

The gluing station 32 glues each of the metal-sputtered and dyed substrates, which are finished with LQ glue coating, with a dummy to form a disc. It is downstream of the metal-sputtering station 3. Each of the glued metal-sputtered substrates proceeds onto the checking station 4 to be checked to determine the quality of each batch of discs. The fourth reader 62 disposed at the checking station 4 transmits a signal periodically to the RFID tag 11 disposed on the disc spindle 1. Then the circuitry of the RFID tag 11 that received the signal from the fourth reader 62 makes sure that each of the glued metal-sputtered substrates goes forward to the checking station 4 to be checked. The signal that was transmitted between the fourth reader 62 and the RFID tag 11 is transmitted to the information system 7 through a network or a computer. The information system 7 reads the signal through a different program to provide a message for the operator on the production line to check and control the discs in the production process.

The checking station 4 is used to checking the glued metal-sputtered substrates to determine the quality of each batch of discs. It is downstream of the gluing station 32. After each of the glued metal-sputtered substrates has been checked, they go forward to the printing station 5 to be printed. The fifth reader 63 disposed at the printing station 5 transmits a signal periodically to the RFID tag 11 disposed on the disc spindle 1. Then the circuitry of the RFID tag 11 that received the signal from the fifth reader 63 makes sure that each of the checked glued substrates goes forward to the printing station 5 to be printed. The signal that was transmitted between the fifth reader 63 and the RFID tag 11 is then transmitted to the information system 7 through a network or a computer. The information system 7 reads the signal through a different program to provide a message for the operator on the production line to check and control the discs in the production process.

The printing station 5 is used for printing the checked and glued substrates. It is downstream of the checking station 4. After each of the checked glued substrates has been printed, they go forward to a packaging station to be packed. A reader disposed at the packaging station transmits a signal periodically to the RFID tag 11 disposed on the disc spindle 1. Then the circuitry of the RFID tag 11 that received the signal from the reader disposed at the packaging station makes sure that each of the printed checking discs goes forward to the packaging station to be packed. The signal that was transmitted to the reader, which is disposed at the packaging station, is transmitted to the information system 7 by the RFID tag 11 through a network or a computer. The information system 7 reads the signal through a different program to provide a message for the operator on the production line to check and control the discs in the production process.

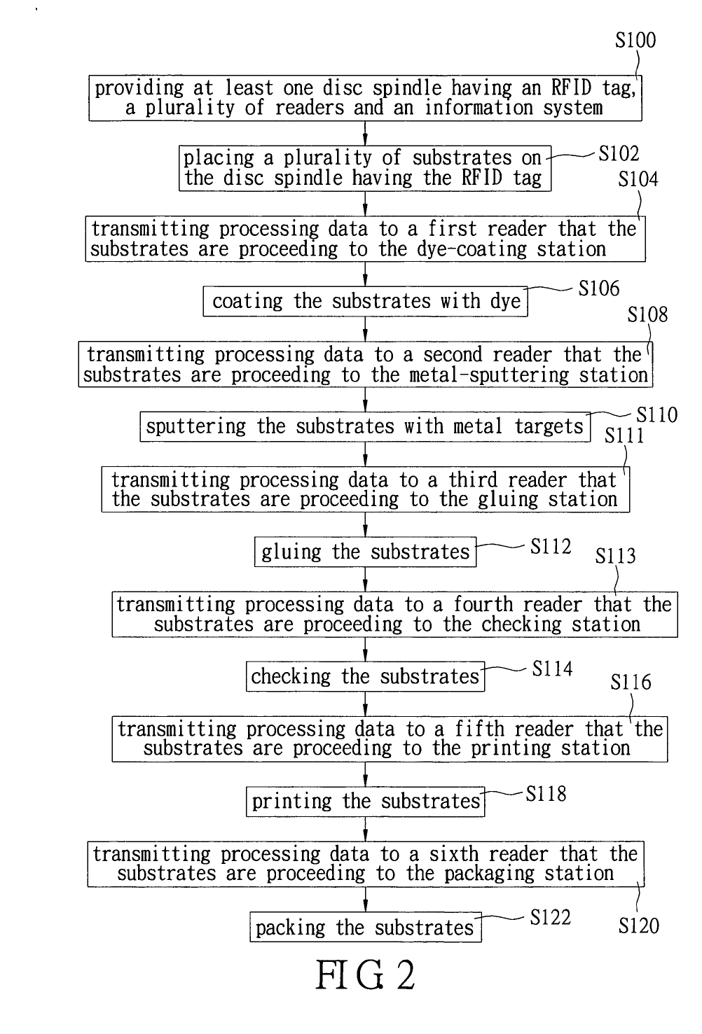

Referring to FIG. 2, the present invention provides a method using RFID tags for tracing a production process of discs, comprising the following steps:

In (S100) Provides a disc spindle 1 which has an RFID tag 11, a plurality of readers 6, 60, 61, 62, and 63 receiving processing data from the RFID tag 11 or transmitting processing data to the RFID tag 11, and an information system 7. The readers 6, 60, 61, 62, and 63 are disposed respectively to each of the stations. The readers 6, 60, 61, 62, and 63 cooperate with the RFID tag 11 attached to the disc spindle 1 to transmit production information of each batch of the discs, including the quality and the quantity of the discs and the production condition of each of the stations for contrasting with production data of each of the stations and for controlling the production process of the discs. The information system 7 is used for receiving transmitted processing data from each of the readers 6, 60, 61, 62, and 63 through a network or a computer. The information system 7 reads the signal that was transmitted between the first reader 6 and the RFID tag 11 through a different program to provide a message for the operator on the production line to check and control the discs in the production process and maintain the accuracy and fluency of the production process.

(S102) involves placing a plurality of substrates on a disc spindle 1 having an RFID tag 11. The RFID tag 11 is attached to the disc spindle 1 and contains the production information of each batch of discs. The disc spindle 1 with the RFID tag 11 is used for controlling the production process of each of the discs. Therefore, when the disc spindle 1 has finished bearing the substrates and moving to the dye-coating station 2 to be coated with dye, the first reader 6 disposed at the dye-coating station 2 transmits a signal periodically to the RFID tag 11 disposed on the disc spindle 1. Then the circuitry of the RFID tag 11 that received the signal transmits the processing data to a first reader 6 informing the information system 7 that the discs is proceeding to the dye-coating station 2 (S104). The RFID tag 11 receives a signal from the first reader 6. The signal that was transmitted between the first reader 6 and the RFID tag 11 is transmitted to the information system 7 through a network or a computer. The information system 7 reads the signal through a different program and makes sure that the substrates goes forward to the dye-coating station 2 to be coated with dye.

After coating dye on the substrates (S106), the dyed substrates goes forward to the metal-sputtering station 3 to be sputtered with metal (Ag, or Au) target. The second reader 60 disposed at the metal-sputtering station 3 transmits a signal periodically to the RFID tag 11 disposed on the disc spindle 1. Then the circuitry of the RFID tag 11 that received the signal transmits a signal to a second reader 60 informing the information system 7 that the dyed substrates are proceeding to the metal-sputtering station 3 (S108). Next, the signal that was transmitted between the second reader 60 and the RFID tag 11 is transmitted to the information system 7 through a network or a computer. The information system 7 reads the signal through a different program and makes sure that the dyed substrates go forward to the metal-sputtering station 3 to be sputtered with metal targets.

After sputtering the metal targets (S110), each of the metal-sputtered and dyed substrates goes forward to the gluing station 32 to be glued with a dummy (this is the same process as for a DVD, but not the same process as for a CD. Therefore, after the metal-sputtered, dyed substrates have been coated with the LQ glue, the rest of the process is the same as that for producing a CD. At that time, the RFID tag 11 transmits processing data to a fourth reader 62 informing the information system 7 that the metal sputtered and dyed substrates that are proceeding to the checking station 4 (S113). The RFID tag 11 sends a signal to the fourth reader 62. The signal that was sent between the fourth reader 62 and the RFID tag 11 is then also transmitted to the information system 7 through a network or a computer. The information system 7 reads the signal through a different program and makes sure that the metal-sputtered and dyed substrates goes forward to the checking station 4 to be checked. (S114)). The third reader 61 disposed at the gluing station 32 transmits a signal periodically to the RFID tag 11 disposed on the disc spindle 1. Then the circuitry of the RFID tag 11 sends a signal to the third reader 61 informing the information system 7 that the metal-sputtered and dyed substrates are proceeding to the gluing station 32 (S111). The RFID tag 11 sends a signal to the third reader 61. The signal that was transmitted between the third reader 61 and the RFID tag 11 is transmitted to the information system 7 through a network or a computer. The information system 7 reads the signal through a different program and makes sure that each of the metal-sputtered and dyed substrates goes forward to the gluing station 32 to be glued.

In (S112) each of the metal-sputtered and dyed substrates are glued with a dummy. Each of the glued metal-sputtered substrates goes forward to the checking station 4 to determine the quality of each batch of discs. The fourth reader 62 disposed at the checking station 4 transmits a signal periodically to the RFID tag 11 disposed on the disc spindle 1. Then the circuitry of the RFID tag 11 sends a signal to a fourth reader 62 informing the information system 7 that the glued and metal-sputtered substrates are proceeding to the checking station 4. The RFID tag 11 sends the processing data to the fourth reader 62. The signal that was transmitted between the fourth reader 62 and the RFID tag 11 is transmitted to the information system 7 through a network or a computer. The information system 7 reads the signal through a different program and makes sure that each of the glued metal-sputtered substrates goes forward to the checking station 4 to be checked.

In (S114) the glued and metal-sputtered substrates are checked, to determine the quality of each batch of discs. After each of the glued metal-sputtered substrates has been checked, they go forward to the printing station 5 to be printed. The fifth reader 63 disposed at the printing station 5 transmits a signal periodically to the RFID tag 11 disposed on the disc spindle 1. Then the circuitry of the RFID tag 11 that received the signal for transmitting processing data of the checked glued substrates that will be transmitted to a fifth reader 63. The RFID tag 11 sends the processing data to the fifth reader 63. The signal that was transmitted between the fifth reader 63 and the RFID tag 11 is then transmitted to the information system 7 through a network or a computer. The information system 7 reads the signal through a different program and makes sure that each of the checked glued substrates goes forward to the printing station 5 to be printed.

In (S118) the checked glued substrates are printed. After each of the checked glued substrates has been printed, they go forward to the packaging station to be packed. A reader disposed at the packaging station transmits a signal periodically to the RFID tag 11 disposed on the disc spindle 1. Then the circuitry of the RFID tag 11 sends a signal to the reader informing the information system 7 that the printed glued substrates are proceeding to the packaging station (S1120). The signal that was transmitted between the reader and the RFID tag 11 is transmitted to the information system 7 through a network or a computer. The information system 7 reads the signal through a different program and makes sure that each of the printed glued substrates goes forward to the packaging station to be packed.

In (S122) the printed and glued substrates are packaged.

There has thus been described a new, novel and heretofore unobvious system and method using RFID tags for tracing a production process of discs that eliminates the aforesaid problem in the prior art. Furthermore, those skilled in the art will readily appreciate that the above description is only illustrative of specific embodiments and examples of the invention. The invention should therefore cover various modifications and variations made to the herein-described structure and operations of the invention, provided they fall within the scope of the invention as defined in the following appended claims.

What is claimed is:

1. A system using RFID tags for tracing a production process of discs, comprising:
At least one disc spindle bearing a plurality of substrates;
At least one RFID tag attached to the disc spindle, and containing production information for each batch of discs;
A dye-coating station used for coating dye to the substrates;
A metal-sputtering station, downstream of the dye-coating station, used for sputtering metal targets to the dyed substrates;
A checking station, downstream of the metal-sputtering station, used for checking the metal-sputtered and dyed substrates to determine the quality of each batch of discs;
A plurality of readers disposed at each of the stations respectively, and cooperating with the RFID tag to transmit production information for each of batch of discs for contrasting with production data of each of the stations and for controlling the production process of the discs; and
An information system used for receiving transmitted data from each of the readers through a network or a computer.

2. The system using RFID tags for tracing a production process of discs of claim 1, further comprising a gluing station, downstream of the metal-sputtering station, used for gluing each of the metal-sputtered and dyed substrates with a dummy to form a disc.

3. A method using RFID tags for tracing a production process of discs, comprising:
(a) providing at least one disc spindle having an RFID tag, a plurality of readers receiving processing data from the RFID tag or transmitting processing data to the RFID tag and an information system used for receiving processing data from each of the readers through a network or a computer;
(b) placing a plurality of substrates on the disc spindle having the RFID tag;
(c) transmitting processing data to a first reader informing the information system that the substrates are proceeding to the dye-coating station;
(d) coating the substrates with dye;
(e) transmitting processing data to a second reader informing the information system that the substrates are proceeding to the metal-sputtering station;
(f) sputtering the substrates with metal targets;
(g) transmitting processing data to a third reader informing the information system that the substrates are proceeding to the checking station;
(h) checking the substrates;
(i) transmitting processing data to a fourth reader informing the information system that the substrates are proceeding to the printing station;
(j) printing the substrates;
(k) transmitting processing data to a reader informing the information system that the substrates are proceeding to the packaging station; and
(l) packing the substrates.

4. A method using RFID tags for tracing a production process of discs, comprising:
(a) providing at least one disc spindle having an RFID tag, a plurality of readers receiving processing data from the RFID tag or transmitting processing data to the RFID tag and an information system used for receiving processing data from each of the readers through a network or a computer;
(b) placing a plurality of substrates on the disc spindle having the RFID tag;
(c) transmitting processing data to a first reader informing the information system that the substrates are proceeding to the dye-coating station;
(d) coating the substrates with a dye;
(e) transmitting processing data to a second reader informing the information system that the substrates are proceeding to the metal-sputtering station;
(f) sputtering the substrate with metal targets;
(g) transmitting processing data to a third reader informing the information system that the substrates are proceeding to the gluing station;
(h) gluing each of the metal-sputtered and dyed substrates with a dummy;
(i) transmitting processing data to a fourth reader informing the information system that the substrates are proceeding to the checking station;
(j) checking the substrates;
(k) transmitting processing data to a fifth reader informing the information system that the substrates are proceeding to the printing station;
(l) printing the substrates;
(m) transmitting processing data to a sixth reader informing the information system that the substrates are proceeding to the packaging station; and
(n) packing the substrates.
